(19) United States
(12) Patent Application Publication
(10) Pub. No.: US 2009/0309097 A1
(43) Pub. Date: Dec. 17, 2009

(54) TESTING DEVICE ON WATER FOR MONITORING VERTICAL MOSFET ON-RESISTANCE

(75) Inventor: Fu-Yuan Hsieh, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/138,412

(22) Filed: Jun. 13, 2008

(51) Int. Cl. H01L 23/58

(52) U.S. Cl. 257/48; 257/E23.001

(57) ABSTRACT

The present invention is to provide a testing device on wafer for monitoring vertical MOSFET on-resistance, formed on a substrate and the substrate comprising a first testing region; and a second testing region; wherein the first testing region and the second testing region are vertical MOSFETs respectively, which comprise at least a common gate region, at least a common drain region, and a plurality of source regions which are separated for each corresponding testing region.

### FIELD OF THE INVENTION

This invention relates to a testing device on wafer for monitoring vertical MOSFET on-resistance and, in particular, to provide at least a testing device manufactured together with main devices, the MOSFET device on wafer prior to backside grinding or a backside metal deposition.

### BACKGROUND

In the structure of a trenched Metal-Oxide-Semiconductor Field Effect Transistor (MOSFET) or other types of vertical MOSFET, the gate region of the transistor is formed on top of a substrate, e.g. in a trench of a trenched MOSFET, and the source region and the drain region are formed on both sides of the substrate of the MOSFET, respectively. This type of vertical MOSFET allows high current to pass from the drain on backside of the substrate to the source through a channel with gate bias voltage for turning on channel region.

For an example, the vertical trenched MOSFET with drain on bottom of substrate, it is impossible to measure On-resistance without having backside grinding and backside Metal deposition. Therefore, there is cost risk to do backside grinding and backside metal without knowing the device having any process issue. Moreover, it also takes few days even more weeks to do backside grinding and backside metal, and any process issue can not be caught in time and lots of wafers in progress may be scrapped.

The present invention provides a testing device on wafer located either in a scribe line or a special area for PCM (process control monitor) for monitoring the on-resistance of a main device, a vertical MOSFET on wafer prior to backside grinding and metal deposition during the MOSFET manufacturing, and improves the lack of the prior art.

### SUMMARY OF THE INVENTION

The invention discloses a testing device on wafer for monitoring vertical MOSFET on-resistance, an on-resistance of a device also named as main device thereafter in main die on wafer, and the testing device is a much smaller than the main device but with same design rule as the main device in scribe line or special area for PCM (process control monitor) for monitoring vertical MOSFET on-resistance before the backside grinding process or the backside metal process of MOSFET manufacturing. Therefore, the present invention can save lot of wafers to be scrapped if any process issue occurred, and scrap any wafer having process issue for saving the cost due to the manufacturing of back grinding or back metal.

The present invention is to provide a testing device on wafer for monitoring vertical MOSFET on-resistance, formed on a substrate and the substrate comprising: a plurality of gate regions comprising a plurality of first testing gate regions, and a plurality of second testing gate regions which are performed a gate effect in the vertical MOSFET; a plurality of source regions comprising a plurality of first testing source regions, and a plurality of second testing source regions which are performed a source effect in the vertical MOSFET; a drain region which is performed a drain effect in the vertical MOSFET; and a front metal layer which comprises at least a common gate metal electrically connected with the corresponding first testing gate region and the corresponding second testing gate region, at least a first testing source metal electrically connected with the corresponding first testing source region, and at least a second testing source metal electrically connected with the corresponding second testing source region, which are separated form each other and are metallic layers formed on a surface of the substrate to define a region for metal connections of the MOSFET; wherein the gate region, the source region, and the drain region are constructed as a semiconductor structure with vertical MOSFET effects; the first testing gate region, the first testing source region, and the drain region are constructed a first testing region; the second testing gate region, the second testing source region, the drain region are constructed a second testing region which is adjoined the first testing region; and the first testing region and the second testing region are constructed the testing device. Besides, a current, defined as Is1s2, flowing between the first testing source region and the second testing source region by biasing gate to turn on channel regions and making a voltage difference, defined as Vs1s2, between the first testing source region and the second testing source region, and an on-resistance, defined as Rds0, of the testing device is equal to Vs1s2 over Is1s2, i.e. Rds0=Vs1s2/Is1s2. In a conclusion, an on-resistance of the main device, defined as Rds, must be coincide with the Rds0 or be linear to the Rds0 so that the Rds of the main device is monitored.

The said gate region is formed with a plurality of trenches distributed horizontally on the substrate, and the each trench is extended downward on the substrate; an insulating layer is coated on an inner face and a top surface of the trenches, and a top surface of the first semiconductor type epitaxial layer while the insulating layer is formed to be a gate oxide layer, an oxide layer for an insulating layer of gates; and the trenches are filled with doped polysilicon to form a gate conductive layer.

The said source regions are formed among the corresponding trenches and insulated from the gate conductive layer by the insulating layer to perform a source effect in the vertical MOSFET.

The said substrate further comprises a plurality of source metal plugs; the each source metal plug is penetrated through the insulating layer covered on the corresponding gate region and the corresponding first semiconductor type body in the source region to connect electrically to the corresponding second semiconductor type body so that the source metal plugs which are corresponding to the first testing region are electrically connected the corresponding first testing source metal with the corresponding first testing source region, and the source metal plugs which are corresponding to the second testing region are electrically connected the corresponding second testing source metal with the corresponding second testing source region.

The said substrate further comprises a plurality of gate metal plugs are inserted respectively in a part, which are corresponding to the gate region, of the trenches; the each gate metal plug is penetrated through the corresponding insulating layer covered on the gate region and the corresponding first semiconductor type body in the source region to connect electrically to the corresponding the gate conductive layer which is doped polysilicon so that the gate conductive layers corresponding to the first testing gate region and the second testing gate region are electrically connected with the common gate metal by the gate metal plug corresponding to the testing device.

The said common gate metal comprises a plurality of first gate contacts which are extended from a lower surface of the common gate metal and penetrated through the insulating layer to electrically connect to the first testing gate region and the second testing gate region.

The said first testing source metal comprises a plurality of the first source contacts which are extended from a lower surface of the first testing source metal and penetrated through the insulating layer to electrically connect the corresponding first semiconductor type body and the corresponding second semiconductor type body of the first testing source region so that the first testing source metal is electrically connected to the first testing source region; and the second testing source metal comprises a plurality of the second source contacts which are extended from a lower surface of the second testing source metal and penetrated through the insulating layer to electrically connect the corresponding first semiconductor type body and the corresponding second semiconductor type body of the second testing source region so that the second testing source metal is electrically connected to the second testing source region.

Furthermore, in the main device, the said gate regions of the substrate comprises a plurality of main gate regions which are performed a gate effect in the vertical MOSFET; the source region further comprises a plurality of main source regions which are performed a source effect in the vertical MOSFET; the front metal layer further comprises at least a main gate metal electrically connected with the corresponding main gate region, and at least a main source metal electrically connected with the corresponding main source region, which are separated form each other and are metallic layers formed on a surface of the substrate to define a region for metal connections of the vertical MOSFET; and the main gate regions, the main source regions, and the drain regions are constructed a corresponding main device. In particular, the source metal plugs which are corresponding to the main device are electrically connected the main source metal with the main source region, and the gate conductive layer corresponding the main gate region is electrically connected with the main gate metal by the gate metal plug corresponding to the main device.

Besides, in the main device, the main gate metal also comprises at least a gate contact for electrically connecting the main gate metal and the main gate region, and the main source metal also comprises a plurality of the third source contacts for electrically connecting the main source metal and the corresponding main source region.

The said testing device is formed on a substrate by a vertical MOSFET manufacturing process which is the same as the process of the main device, and it is better that the testing device is formed on a substrate together with the main device.

The said testing device is formed in an area which is selected from a scribe line or a PCM area, a sacrificial part of the substrate.

The said vertical MOSFET is selected form a vertical MOSFET formed with closed cells or stripe cells.

The said first testing region and the second testing region are on-state while the common gate metal is applied a bias voltage over a threshold voltage, the first testing source metal is applied a driving voltage, and the second testing source metal is grounded, and a current flow occurs as shown in FIG. 5 from the first testing source region through the first channel region down to the common drain region, then up to the second channel region and reaches to the second testing source region adjacent to the first testing source region in the testing device.

In the said embodiment, an on-resistance value of the main device is estimated by measuring an on-resistance value of the testing device on-state.

### BRIEF DESCRIPTION OF THE DRAWINGS

The present invention can be more fully understood by reading the following detailed description of the preferred embodiments, with reference made to the accompanying drawings, wherein:

FIG. 1 is a top view on a wafer according to a testing device on wafer for monitoring vertical MOSFET on-resistance of the present invention;

FIG. 2A is a enlarge view of the FIG. 1 according to a source region in the main device of the present invention;

FIG. 2B is another enlarge view of the FIG. 1 according to a gate region in the main device of the present invention;

FIG. 3 is more another enlarge view of the FIG. 1 according to the testing device of the present invention;

FIG. 4 is a sectional view taken along a line I-I in the FIG. 2A according to the main device of the present invention;

FIG. 5 is a sectional view taken along a line II-II in the FIG. 3 according to the testing device of the present invention;

FIG. 6 is a sectional view taken along a line I-I in the FIG. 2A according to the main device of the present invention in another embodiment;

FIG. 7 is a sectional view taken along a line II-II in the FIG. 3 according to the testing device of the present invention in the same embodiment of the FIG. 6;

FIG. 8 is a sectional view taken along a line I-I in the FIG. 2A according to the main device of the present invention in more another embodiment;

FIG. 9 is a sectional view taken along a line II-II in the FIG. 3 according to the testing device of the present invention in the same embodiment of the FIG. 8;

FIG. 10 is a enlarge view of the FIG. 1 according to more another embodiment of the present invention; and

FIG. 11 is another enlarge view of the FIG. 1 according to more another embodiment of the present invention.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

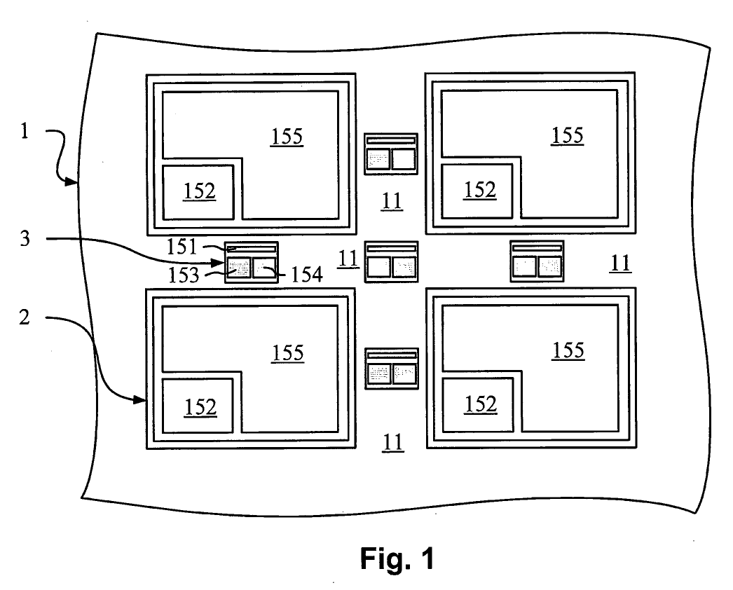

Referring to FIG. 1, the FIG. 1 is a top view on a wafer according to a testing device on wafer for monitoring vertical MOSFET on-resistance of the present invention. As the FIG. 1 shows, a plurality of main devices (2) and at least a testing device (3) are formed on a substrate (1) which is a substrate for a MOSFET manufacturing process and is usually called wafer. The said main devices (2) and the testing device (3) are formed by the same MOSFET design rule and manufacturing process. In a best embodiment, the testing device (3) is formed on the substrate (1) together with the main device (2). In particular, the said testing device (3) comprises two vertical MOSFETs, which are adjacent to each other and are much smaller than the main device (2), with common gate and drain but separated source metals for monitoring an on-resistance of the main devices (2) without having backside grinding or backside metal deposition during the MOSFET manufacturing process.

In the said embodiment above, the each main device (2) is formed in a corresponding main die on the substrate (1) and the main device (2) are aligned in array while the space among the main devices (2) are defined as a plurality of scribe lines (11) which are shown in the FIG. 1 and are sacrificial during the cutting process of the substrate (1) to segment each main device (2) from the substrate (1) before packaging of the main devices (2). The said testing device (3) can be formed in the scribe lines (11) defined above while the testing device (3) works for monitoring the main device (2) before an backside grinding process or the backside metal process, a process forms an electrically connecting metal for the drain region of MOSFET, so that the main die for the main devices (2) on the wafer isn't diminished due to the testing device (3). For another embodiment, the said testing device (3) also can be located in a special area (not shown), another sacrificial part, for PCM (process control monitor) for monitoring the electrical characteristics of a main device (2) during one step or more steps of the MOSFET manufacturing.

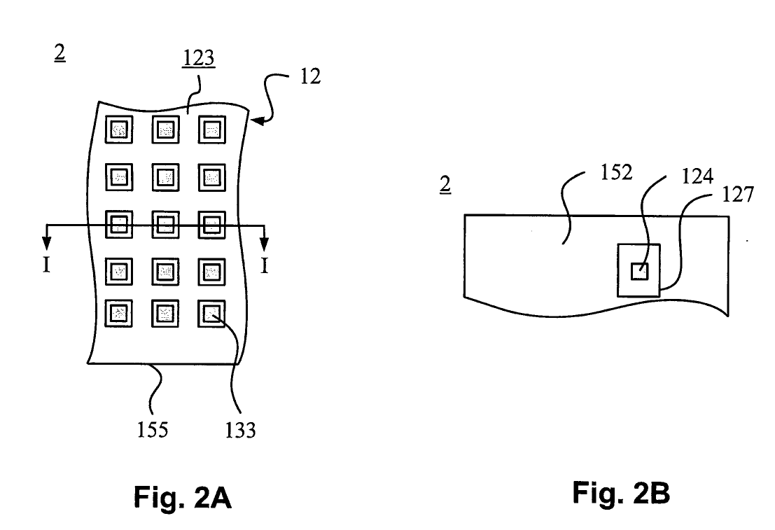

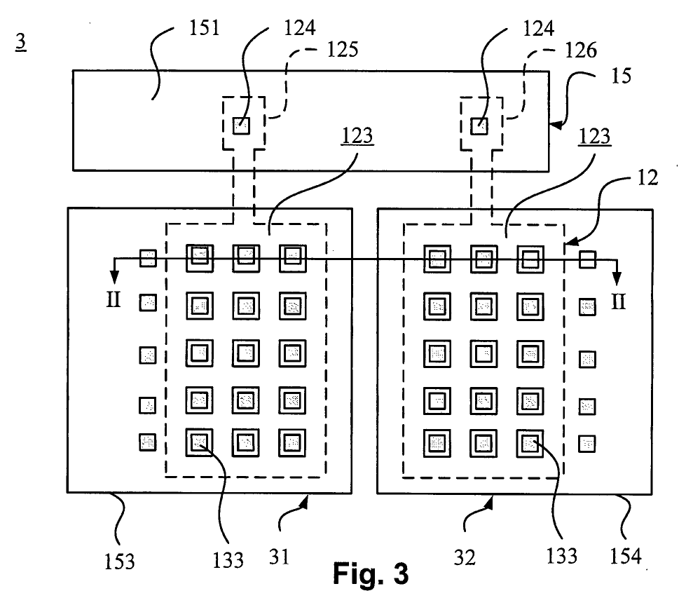

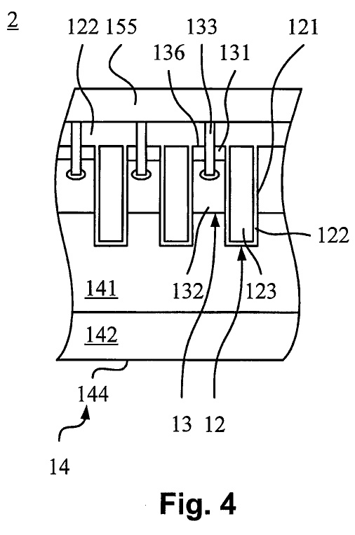

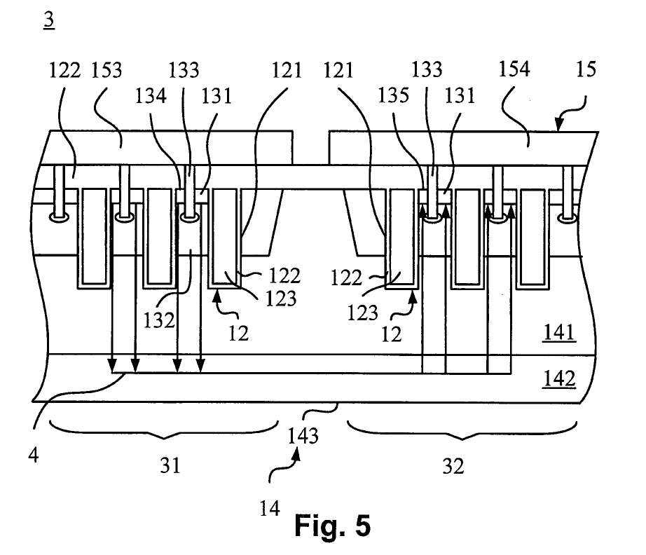

FIGS. 2A-2B, and FIGS. 3-5 refer to the different aspects of FIG. 1. FIG. 2A is a enlarge view of the FIG. 1 according to a source region in the main device of the present invention. FIG. 2B is another enlarge view of the FIG. 1 according to a gate region in the main device of the present invention. FIG. 3 is more another enlarge view of the FIG. 1 according to the testing device of the present invention. FIG. 4 is a sectional view taken along a line I-I in the FIG. 2A according to the main device of the present invention. FIG. 5 is a sectional view taken along a line II-II in the FIG. 3 according to the testing device of the present invention. The description following is more detail about the present invention.

In an embodiment, the substrate (1) shown in FIG. 1, comprises a plurality of gate regions (12) shown in FIGS. 2A and 3, a plurality of source regions (13) shown in FIGS. 4 and 5, a plurality of drain regions (14) shown in FIGS. 4 and 5, and a front metal layer (15) shown in FIGS. 4 and 5. The gate regions (12), the source regions (13), and the drain regions (14) are constructed as a plurality of semiconductor cells with vertical MOSFET effect. The front metal layer (15) is an electrically connection and a metallic layer formed on a surface of the substrate (1) to define a region for metal connections of the vertical MOSFET.

Referring to FIG. 3, the said testing device (3) comprises a first testing region (31) and a second testing region (32) which is adjacent to each other. The first testing region (31) and the second testing region (32) have a common gate region and a common drain to perform a MOSFET effect without a backside grinding or a backside metal.

Referring to FIGS. 4 and 5, the said drain region (14) comprises an N⁺-type semiconductor layer (142), a layer with strongly n-type doping, and an N-type epitaxial layer (141) which is an epitaxial layer with less n-type doping than the N⁺-type semiconductor layer (142). The N-type epitaxial layer (141) is formed on the N⁺-type semiconductor layer (142) to constitute the said drain region (14) which is performed a drain effect in MOSFET. In an embodiment, the N-type epitaxial layer (141) and the N⁺-type semiconductor layer (142) of the drain region (14) are formed respectively at an upper part and a lower part of the substrate (1), and the N⁺-type semiconductor layer (142) has higher n-type doping concentration than the N-type epitaxial layer (141). Besides, the drain regions (14) are distinguished into at least a common drain region (143) corresponding to the testing device (3) shown in FIG. 5, and at least a main drain region (144) which is corresponding to the main device (2) shown in FIG. 4.

Referring to FIGS. 2A, 2B, 3, 4, and 5, the said gate regions (12) are formed at an upper part of the N-type epitaxial layer (141) to perform a gate effect in MOSFET, and comprises a plurality of first testing gate regions (125) according to the first testing region (31), a plurality of second testing gate regions (126) according to the second testing region (32), and a plurality of main gate regions (127) according to the main device (2). In an embodiment, the N-type epitaxial layer (141) is applied a silicon etching process to form a plurality of trenches (121), which are extended downward and aligned horizontally according to the areas of the main device (2) and the testing device (3), and the trenches of the gate regions (12) are defined. Besides, the depth and the width of the said trenches and the distance between the adjacent trenches must be selected to optimum sizes because the breakdown voltage and the on-resistance characteristic of the MOSFET depend thereupon. However, these sizes are also related to the state of formation of an impurity diffusion layer. Moreover, an insulating layer (122) is coated on an inner face and a top surface of the trenches (121), and a top surface of the N-type epitaxial layer (141) while the insulating layer (122) is formed by a deposition or thermally grown process to be a gate oxide layer, an oxide layer for an insulating layer of gates. The trenches (121) are filled with doped polysilicon to form a gate conductive layer (123). Then, the trenches (121) according to the first testing region (31) are defined as the first testing gate regions (125), the trenches (121) according to the second testing region (32) are defined as the second testing gate regions (126), and the trenches (121) according to the main device (2) are defined as the main gate regions (127).

Referring to FIGS. 4 and 5, the said source region (13) comprises a plurality of the active regions each of which comprises a plurality of N⁺-type bodies (131) and a plurality of P-type bodies (132). The P-type bodies (132) are P-type semiconductor formed on a plurality of upper parts of the N-type epitaxial layer (141) by ion implantation, and the N⁺-type bodies (131) are N-type semiconductor formed on a plurality of upper parts of the P-type bodies (132) by ion implantation. The N⁺-type bodies (131) have higher doping concentration than the N-type epitaxial layer (141). The N⁺-type bodies (131) and the P-type bodies (132), the said active regions, are formed among the trenches (121) and insulated from the gate conductive layer (123) by the insulating layer (122) to perform a source effect in MOSFET. The N⁺-type bodies (131) and the P-type bodies (132) according to the first testing region (31) are defined corresponding first testing source regions (134), the N⁺-type bodies (131) and the P-type bodies (132) according to the second testing region (32) are defined corresponding second testing source regions (135), and the N⁺-type bodies (131) and the P-type bodies (132) according to the main device (2) are defined corresponding main source regions (136).

Referring to FIGS. 1, 2A, 2B, 3, 4, and 5, the said front metal layer (15) can be made of metal or an electrically conductive alloy and comprises at least a common gate metal (151 in FIG. 3) according to the first testing gate region (125) and the second testing gate region (126) in the testing device (3) shown in FIGS. 1, 3, and 5, at least a main gate metal (152) according to the main gate region (127) in the main device (2) shown in FIGS. 1, 2A, 2B, and 4, at least a first testing source metal (153) according to the first testing source region (134) in the testing device (3), at least a second testing source metal (154) according to the second testing source region (135) in the testing device (3), and at least a main source metal (155) according to the main source region (136) in the main device (2). The common gate metal (151) is electrically connected to both the first testing gate region (125) and the second testing gate region (126), the main gate metal (152) is electrically connected to the main gate region (127), the first testing source metal (153) is electrically connected to the first testing source region (134), the second testing source metal (154) is electrically connected to the second testing source region (135), and the main source metal (155) is electrically connected to the main source region (136).

The first testing gate region (125), the first testing source region (134), and the common drain region (143) are constructed as a semiconductor structure, defined as the first testing region (31), with MOSFET effect, and the second testing gate region (126), the second testing source region (135), and the main drain region (144) are constructed as another semiconductor structure with MOSFET effect, defined as the second testing region (32) which is adjoined the first testing region (31) through the common drain region (143). Besides, in the main device (2), the main gate region (127), the main source region (136), and the main drain region (144) are constructed as a semiconductor structure with MOSFET effect and formed the said main devices (2).

Base the description above as FIG. 5 shows, the testing device (3) comprised the first testing region (31) and the second testing region (32) is on-state while the common gate metal (151) is applied a bias voltage over a threshold voltage, the first testing source metal (153) is applied a driving voltage, and the second testing source metal (154) is grounded, and a current flow (4) occurs from the first testing source region (134) through the common drain region (143) to the second testing source region (135) in the testing device (3). Therefore, the on-resistance value of the testing device (3) being on-state can be measured, and the on-resistance value of the main device (2) can be calculated from the on-resistance value of the testing device (3). Finally, the on-resistance of the main device (2) can be monitored prior to backside grinding or backside metal deposition on the drain (142) according to the main drain region (144) in the main device (2).

Referring to FIGS. 2A, 3, 4, and 5, in the said embodiment above, a plurality of source metal plugs (133) are formed corresponding to the each source regions (13). The each source metal plug (133) is penetrated through the first insulating layer (122) covered on the corresponding gate region (12) and the corresponding N⁺-type body (131) in the source region (13) to connect electrically to the corresponding P-type body (132). Therefore, the source metal plugs (133) in the first testing region (31) are electrically connected the first testing source metal (153) and the corresponding first testing source region (134), the source metal plugs (133) in the second testing region (32) are electrically connected the second testing source metal (154) and the corresponding second testing source region (135), and the source metal plugs (133) in the main device (2) are electrically connected the main source metal (155) and the corresponding main source region (136).

In the said embodiment above, a plurality of gate metal plugs (124) in FIG. 2B are inserted respectively in a part, which are corresponding to the gate region (12), of the trenches (121). The each source metal plug (133) in FIGS. 2A and 4 is penetrated through the insulating layer (122) covered on the corresponding gate region (12) and the corresponding N⁺-type body (131) in the source region (13) to connect electrically to the corresponding P-type body (132). Therefore, the gate conductive layers (123) corresponding to the first testing gate region (125) and the second testing gate region (126) are both electrically connected to the common gate metal (151) by the gate metal plug (124) corresponding to the testing device (3). The gate conductive layer (123) corresponding to the main gate region (127) is electrically connected to the main gate metal (152) by the gate metal plug (124) corresponding to the main device (2). A current, defined as Is1s2, flowing between the first testing source region (134) and the second testing source region (135) by biasing gate to turn on channel regions and by making a voltage difference, defined as Vs1s2, between the first testing source region (134) and the second testing source region (135), and an on-resistance, defined as Rds0, of the testing device (3) equal to Vs1s2 over Is1s2, i.e. Rds0=Vs1s2/Is1s2, is obtained. In a conclusion, an on-resistance of the main device (2), defined as Rds, must be coincide with the Rds0 or be linear to the Rds0 so that the Rds of the main device (2) is monitored.

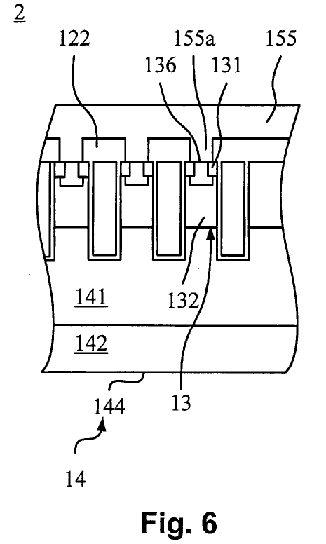

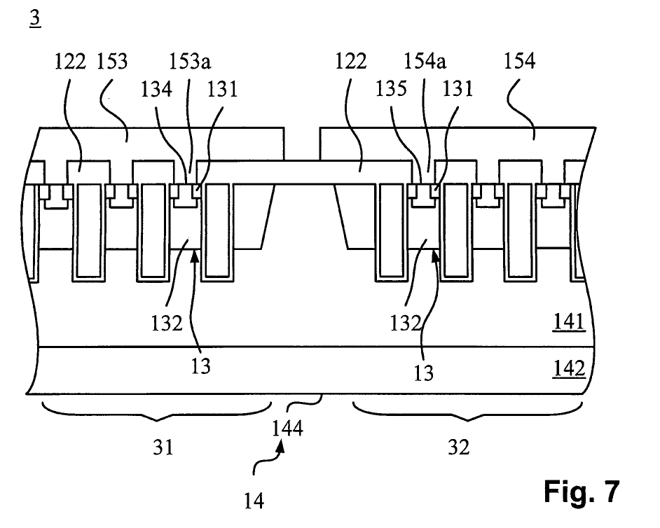

Referring to FIGS. 6 and 7, the FIG. 6 is a sectional view taken along a line I-I in the FIG. 2A according to the main device of the present invention in another embodiment, and the FIG. 7 is a sectional view taken along a line II-II in the FIG. 3 according to the testing device of the present invention in the same embodiment of the FIG. 6. The description following is more detail about the present invention. The main device (2) and the testing device (3) can both be vertical MOSFETs with planar source contacts. In FIG. 7 the each P-type body (132) is penetrated through the N⁺-type body (131) to extend to the upper surface of the N-type epitaxial layer (141). The said first testing source metal (153) can comprise a plurality of first source contacts (153a) which are extended from a lower surface of the first testing source metal (153) and penetrated through the insulating layer (122) to electrically connect the corresponding N⁺-type body (131) and the corresponding P-type body (132) in the first testing source region (134). The first testing source metal (153) is electrically connected to the first testing source region (33). The said second testing source metal (154) can comprise a plurality of second source contacts (154a) which are extended from a lower surface of the second testing source metal (154) and penetrated through the insulating layer (122) to electrically connect the corresponding N⁺-type body (131) and the corresponding P-type body (132) in the second testing source region (135) so that the second testing source metal (154) is electrically connected to the second testing source region (135). The main source metal (155) in the main device (2) shown in FIG. 6 can comprise a plurality of third source contacts (155a) which are extended from a lower surface of the main source metal (155) and penetrated through the insulating layer (122) to electrically connect the corresponding N⁺-type body (131) and the corresponding P-type body (132) in the main source region (136) so that the main source metal (155) is electrically connected to the main source region (136).

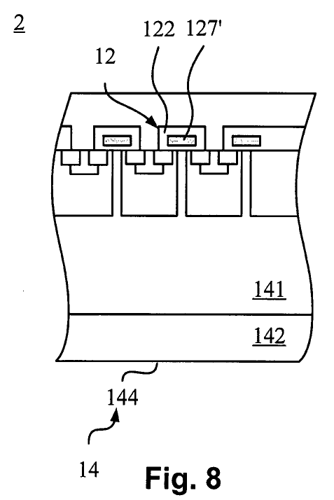

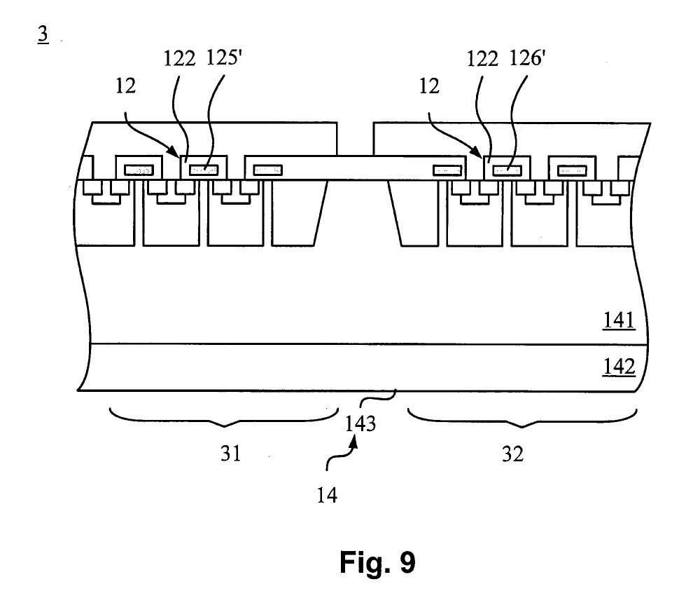

Referring to FIGS. 8 and 9, the FIG. 8 is a sectional view taken along a line I-I in the FIG. 2A according to the main device of the present invention in more another embodiment, and the FIG. 9 is a sectional view taken along a line II-II in the FIG. 3 according to the testing device of the present invention in the same embodiment of the FIG. 8. The main device (2) and the testing device (3) can be vertical MOSFETs with planar gate regions. The said gate conductive layer (123) of the gate region (12) in the FIGS. 8 and 9 is formed in the insulating layer (122) and is formed a plurality of first testing gate regions (125′) in the FIG. 9 according to the first testing region (31), a plurality of second testing gate regions (126′) in the FIG. 9 according to the second testing region (32), a plurality of main gate regions (127′) in the FIG. 8 according to the main device (2).

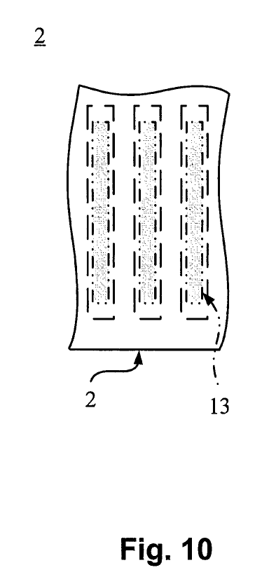

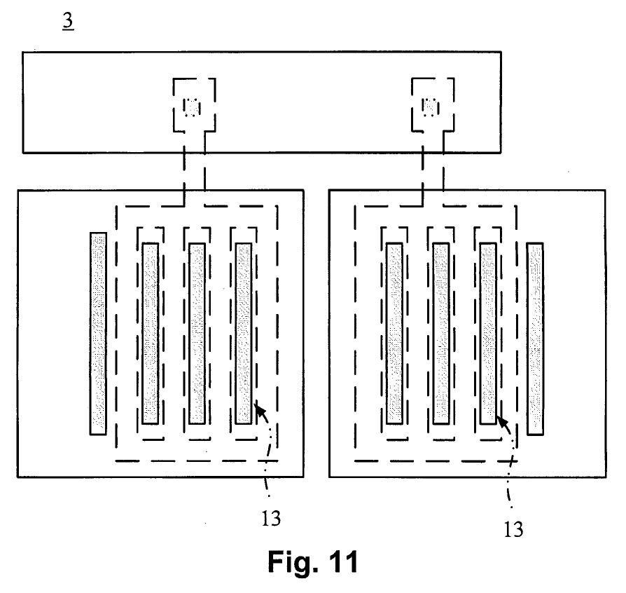

Referring to FIGS. 10 and 11, the FIG. 10 is a enlarge view of the FIG. 1 according to more another embodiment of the present invention, and the FIG. 11 is another enlarge view of the FIG. 1 according to more another embodiment of the present invention. In the embodiment shown in the FIGS. 10 and 11, the main device (2) and the testing device (3) are MOSFETs with stripe cells since the source region (13) is formed as stripe shape in the top view.

In the said embodiment, description has been directed to the N-channel MOSFET structure, and the N-type semiconductor can be defined a first type semiconductor while the P-type semiconductor can be defined a second type semiconductor. However, by inverting the conductive type, this invention is also applicable to a P-channel MOSFET structure. It's mean that the first type semiconductor can be the P-type semiconductor, and of course the second type semiconductor is the N-type semiconductor.

In the each said embodiment above, the stack structure of the testing device is formed by the same manufacturing process of the main device. In general cases, the stack structure of the testing device is the same as the stack structure of the main device even the testing device is near a combination of two MOSFET devices. Therefore, there is no more manufacturing process to form the testing device, and a testing of the testing devices can estimate some electrical characteristics of the main device before a back metal process of the main device. On the other words, the each main device, a MOSFET device, on a wafer without a back metal, a connect metal for the drain region, can be qualified and distinguished whether quantitatively good or not by the monitoring the testing device on the same wafer.

The said embodiments of the present invention are all formed as the trenched MOSFET with metal plug source contacts or planer source contacts, but the present invention is not restricted in those types of MOSFET. The present invention is concerned about the testing device which can be formed synchronously with the main devices, and the testing device can be operated to result a MOSFET effect without back grinding or back metal of the drain region. For an example, the MOSFET of the present invention can also apply for the planar MOSFET which is formed with planar the gate region.

Although various embodiments are specifically illustrated and described herein, it will be appreciated that modifications and variations of the present invention are covered by the above teachings and are within the purview of the appended claims without departing from the spirit and intended scope of the invention.

What is claimed is:

1. A testing device on wafer for monitoring vertical MOSFET on-resistance, formed on a substrate and the substrate comprising:
a first testing region; and
a second testing region;
wherein the first testing region and the second testing region are vertical MOSFETs respectively, which comprise at least a common gate region, at least a common drain region, and a plurality of source regions which are separated for each corresponding testing region.

2. The testing device of claim 1, wherein the front metal layer which comprises at least a common gate metal electrically connected with the corresponding regions with MOSFET gate effects in the first testing source and the second testing source, at least a first testing source metal electrically connected to the corresponding source region in the first testing region, and at least a second testing source metal electrically connected to the corresponding source region in the second testing region, which are separated form each other and are metallic layers formed on the surface of the substrate to define a region for metal connections of the MOSFETs.

3. The testing device of claim 1, wherein the common gate region is formed with a plurality of trenches extended downward and aligned horizontally on the substrate; an insulating layer is coated on an inner face and a top surface of the trenches, and a top surface of the first semiconductor type epitaxial layer while the insulating layer is formed to be a gate oxide layer, an oxide layer for an insulating layer of gates; and the trenches are filled with doped polysilicon to form a gate conductive layer.

4. The testing device of claim 3, wherein the source regions are formed among the corresponding trenches and insulated from the gate conductive layer by the insulating layer to perform a source effect in the vertical MOSFET.

5. The testing device of claim 3, wherein the substrate further comprises a plurality of source metal plugs; the each source metal plug is penetrated through the insulating layer covered on the corresponding common gate region and the corresponding first semiconductor type body in the corresponding source region to connect electrically to the corresponding second semiconductor type body so that the source metal plugs which are corresponding to the first testing region are electrically connected the corresponding source metal to the corresponding source region in the first testing region, and the source metal plugs which are corresponding to the second testing region are electrically connected the corresponding source metal to the corresponding source region in the second testing region.

6. The testing device of claim 3, wherein the substrate further comprises a plurality of gate metal plugs are inserted respectively in a part of the each trench corresponding to the common gate region; the each gate metal plug is penetrated through the corresponding insulating layer covered on the common gate region to connect electrically to the gate conductive layer so that the gate conductive layers corresponding to the common gate region in the first testing region and the common gate region in the second testing region are electrically connected with the common gate metal by the gate metal plug corresponding to the testing device.

7. The testing device of claim 3, wherein the common gate metal comprises a plurality of first gate contacts which are extended from a lower surface of the common gate metal and penetrated through the insulating layer to electrically connect to the common gate region in the first testing region and the common gate region in the second testing region.

8. The testing device of claim 3, wherein the first testing source metal comprises a plurality of the first source contacts which are extended from a lower surface of the first testing source metal and penetrated through the insulating layer to electrically connect the corresponding first semiconductor type body and the second semiconductor type body of the corresponding source region in the first testing region so that the first testing source metal is electrically connected to the corresponding source region in the first testing region; and the second testing source metal comprises a plurality of the second source contacts which are extended from a lower surface of the second testing source metal and penetrated through the insulating layer to electrically connect the first semiconductor type body and the second semiconductor type body of the corresponding source region in the second testing region so that the second testing source metal is electrically connected to the corresponding source region in the second testing region.

9. The testing device of claim 1, wherein the testing device is formed in an area which is selected from a scribe line or a PCM area, a sacrificial part of the substrate.

10. The testing device of claim 1, wherein the vertical MOSFET is selected form a vertical MOSFET formed with closed cells or stripe cells.

11. The testing device of claim 1, wherein the first testing region and the second testing region are on-state while the common gate metal is applied a bias voltage over a threshold voltage, the first testing source metal is applied a driving voltage, and the second testing source metal is grounded, and a current flow occurs from the source region in the first testing region through the common drain region to the source region in the second testing region in the testing device.

12. The testing device of claim 1, wherein the substrate further comprises a main device which is a vertical MOSFET formed on the substrate by manufacturing process the same as the testing device.

13. The testing device of claim 12, wherein an on-resistance value of the main device is estimated and monitored by measuring an on-resistance of the testing device.

14. The testing device of claim 12, wherein the main device is formed on a substrate together with the testing device.
